(19) United States
(12) Patent Application Publication
(10) Pub. No.: US 2010/0051190 A1
(43) Pub. Date: Mar. 4, 2010

(54) METHOD FOR APPLYING AN ADHESIVE LAYER ON THIN CUT SEMICONDUCTOR CHIPS OF SEMICONDUCTOR WAFERS

(75) Inventors: Simon Jerebic, Regensburg (DE); Peter Strobel, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/721,067

(22) PCT Filed: Nov. 23, 2005
(86) PCT No.: PCT/DE2005/002116

§ 371 Date: Nov. 16, 2009

(30) Foreign Application Priority Data
Dec. 9, 2004 (DE) 10 2004 059 599.2

(51) Int. Cl. H01L 21/70; C09J 7/02

(52) U.S. Cl. 156/248

(57) ABSTRACT

The invention relates to a method for applying an adhesive layer to ground-thin or thinned semiconductor chips of a semiconductor wafer. In this case, the adhesive layer, with the aid of an adhesive film which is entirely composed of precurable adhesive, is introduced relatively early into a method for the thinning by grinding, separation and singulation of a semiconductor wafer to form thinned semiconductor chips, and is finally used further in the semiconductor device into which the thinned semiconductor chip is to be incorporated.

The invention relates to a method for applying an adhesive layer to ground-thin semiconductor chips of a semiconductor wafer. Thinning by grinding is known from the document DE 100 48 881. In this method, a product wafer, whose active surface is connected to a carrier wafer, is thinned by grinding from its rear side and the ground-thin product wafer is subsequently sawn into individual semiconductor chips. In this known method there is a problem in removing the thinned semiconductor chips from a carrier wafer without destroying them, and in preparing them for further processing to form a semiconductor device with an adhesive layer on the rear side for a so-called “die attach”. With increasing miniaturization of the semiconductor chips, in particular with increasing reduction of the volume of the semiconductor chip by decreasing its thickness by thinning by etching or thinning by grinding to a thickness of just a few tens of pm, it becomes increasingly difficult to handle semiconductor chips in a semiconductor chip mounting installation or, after the thinning by grinding process, in a corresponding lapping and polishing device.

At the present time the failure rate when using standard handling tools in a semiconductor chip mounting installation is already about 20%. Given such a high proportion of damaged thinned semiconductor chips, particularly in the case of semiconductor chips intended for a radiofrequency application, it is necessary to reduce this failure rate. Particularly serious failure rates occur in the installation regions for so-called “die bonding” or “die attach”. In this case, the semiconductor chips are lifted off from a single-sided adhesive carrier film and brought to a position in which the thinned semiconductor chip is fixed onto a chip island of a system carrier in a device position for producing an electronic device.

For the lift-off of the semiconductor chips from a supporting and transporting film with an adhesive layer and the transfer to a vacuum pipette, the document 10 DE 101 59 974 discloses a suitable mounting installation. In this case, the thinned semiconductor chip is picked up by the suction nipple of the vacuum pipette and brought to a corresponding position for the purpose of soldering or adhesive bonding, in which position is situated a chip island of a leadframe for receiving the semiconductor chip or a wiring substrate with a correspondingly provided contact pad for receiving the ground-thin semiconductor chip. The detachment of the rear side of the semiconductor chip from the adhesive of the supporting and transporting film is extremely problematic in this case since it is necessary to apply high forces that make it possible to overcome the adhesion between semiconductor chip and adhesive of the film. This is particularly problematic for ground-thin semiconductor chips and entails the risk of fracture of the ground-thin semiconductor chips during lift-off.

A further disadvantage is that after this detachment operation, a semiconductor chip is available which still has no fixing aids whatsoever for further processing and hence for fixing on a semiconductor chip island of a leadframe or for fixing on a contact pad or on a so-called “die bond pad”. Such fixing aids are adhesive coatings or solder coatings on the rear side of the semiconductor chip by means of which the semiconductor chip can be fixed on the provided positions of the chip islands or the contact pads with simultaneous electrical contact-connection. The application of such auxiliary substances to a ground-thin semiconductor chip turns out to be correspondingly difficult and leads to an increased reject rate in the case of the ground-thin or thinned semiconductor chips.

It is an object of the invention to specify a method for applying an adhesive layer to thinned semiconductor chips of a semiconductor wafer in which the semiconductor chip does not have to be individually provided with such an adhesive layer, rather a multiplicity of semiconductor chips can be provided with a corresponding adhesive layer without the risk of fracture of the semiconductor chips.

This object is achieved by means of the subject matter of the independent claims. Advantageous developments of the invention emerge from the dependent claims.

The invention provides a method for applying an adhesive layer to ground-thin semiconductor chips of a semiconductor wafer, wherein the method has the following method steps. The first step involves applying an adhesive film having an adhesive that can be precured by means of irradiation to a supporting and transporting film.

Separating joints are then introduced into the adhesive film. In this case, the separating joints correspond in terms of arrangement and width to the arrangement and width of separating grooves of a thinned semiconductor wafer separated into thinned semiconductor chips. Said semiconductor wafer is arranged with the active top sides of the semiconductor chips on a supporting plate. The thinned and separated semiconductor wafer is then applied by its rear side to the adhesive film with the separating grooves being aligned with the separating joints. Finally, the supporting plate can be removed. The supporting and transporting film is then irradiated, the adhesive of the adhesive film precuring. In this case, the adhesion of the adhesive film at the rear sides of the semiconductor chips is intensified, while the adhesion of the adhesive film to the supporting and transporting film is reduced. Afterward, the thinned semiconductor chips with adhering adhesive layer can successively be lifted off from the supporting and transporting film.

This method advantageously exploits the fact that the adhesion of the precured adhesive of the adhesive film to the rear sides of the semiconductor chips is greater than the adhesion to the supporting and transporting film. This adhesion is so low that, during lift-off of the ground-thin semiconductor chips, the adhesive film with precured adhesive can be released from the supporting and transporting film without measurable loading of the ground-thin semiconductor chip. The adhesion of the adhesive film to the supporting and transporting film is just enough to maintain the positions of the semiconductor chips of the separated semiconductor wafer during handling and transport on 25 the film.

The precured adhesive forms, on the rear side of the semiconductor chips, an adhesive layer connected to the semiconductor chip. In this case, adhesive layer of the adhesive film is understood here to mean an adhesive layer that occupies the entire volume and the thickness of the adhesive film.

Since, on the one hand, the thickness of said adhesive layer on the rear sides of the semiconductor chips corresponds to the thickness of the adhesive film, the forces during the lift-off of the thinned semiconductor chip from the supporting and transporting film arranged underneath are distributed more uniformly over the adhesive layer and over the rear side of the semiconductor chip than in previous lift-off techniques and, moreover, the lower adhesion of the procured adhesive to the supporting and transporting film has an effect during the lift-off of the thinned semiconductor chips.

A further advantage of this method is that, on the one hand, the thinned semiconductor chips at risk of fracture do not have to be individually provided with an adhesive layer on the rear side after singulation, and it is advantageous, on the other hand, that all the processes for applying films and removing films can be effected simultaneously for a multiplicity of semiconductor chips on the entire wafer separated into semiconductor chips. The risk of fracture of individual semiconductor chips is minimized in the case of this joint further processing. The adhesion differences are coordinated with one another by material differences and surface preparations.

It is thus advantageous that the supporting and transporting film has for example a smooth surface of a plastic film, while the rear sides of the semiconductor chips of a semiconductor wafer, on account of the preceding grinding processes, can be provided with a residual roughness that supports the adhesion differences with respect to a precured adhesive film. Furthermore, it is possible for films which have a coating of olefin or paraffin chain molecules to be used as the supporting and transporting film, such that an intensive adhesive bonding with the adhesive film is impeded and it is possible to realize a significant adhesion difference with regard to the rear side of the semiconductor chip and the top side of the supporting and transporting film.

The introduction of the separating joints into the composite body composed of supporting and transporting carrier is preferably effected by means of sawing technology. In this case, by means of a saw blade having a thickness of a few tens of micrometers, a separating joint having a corresponding width that corresponds to the saw blade thickness is introduced and a separating joint depth T that is greater than or equal to the thickness w of the adhesive film is sawn into the composite body. Consequently,

T≧w.

This has the advantage that the adhesive film is separated into individual mutually separate adhesive layers, wherein the areal extent of an individual adhesive layer corresponds to the areal extent of a semiconductor chip.

Instead of sawing technology, in a further preferred exemplary implementation of the method, laser ablation can be used for introducing the separating joints into the adhesive film. Laser ablation has the advantage that, given a suitable choice of the material combinations, it is possible to slow down or stop the laser ablation at the boundary layer between adhesive film and supporting and transporting film.

Scribing and/or cutting techniques can also be used for introducing the separating joints into the plastic films. While the scribing technique corresponds to the sawing technique in terms of the result, a grid-shaped cutting blade can be used to impress all the separating joints into the plastic film simultaneously in a single manufacturing step.

Prior to application of the adhesive film to the thinned semiconductor chip, the method has the following method steps. The first step involves producing a semiconductor wafer having an active top side and an opposite rear side, which wafer is also called product wafer in the art. A multiplicity of semiconductor chip positions are arranged in rows and columns on the active top side of such a product wafer, separating tracks being provided between the semiconductor chip positions. In a next step, separating grooves are introduced into the semiconductor wafer along the separating tracks.

In this case, the depth t of the separating grooves is smaller than the thickness D of the semiconductor wafer. Furthermore, the depth t of the separating grooves is greater than or equal to the thickness d of the thinned semiconductor chips provided. Thus, the semiconductor wafer, which usually has a thickness D of between 500 μm and 750 μm given a diameter of between 150 mm and 300 mm, still holds together completely as a semiconductor slice despite separating grooves, especially as the separating grooves reach a depth that is only a few micrometers deeper than the thickness of the semiconductor chips to be thinned. The thickness of such thinned semiconductor chips is 30 μm to 200 μm. Therefore, enough material still remains to ensure the cohesion of the semiconductor wafer in this fabrication phase.

In this state, the active top sides of the semiconductor wafer are uncovered, while the rear side of the semiconductor wafer is applied for example on a vacuum holder of a separating apparatus such as an air-mounted diamond saw or a laser beam removal apparatus for semiconductor wafers. In order to protect the sensitive active top sides of the semiconductor chips after the introduction of the separating grooves, an adhesive protective film and a supporting plate are then applied to the top side with separating grooves. Said supporting plate may simultaneously constitute a tool of a grinding, lapping and/or polishing machine. Such tools are preferably metal disks which are adapted to the size of the semiconductor slices and which receive the semiconductor wafers with their top sides having separating grooves and press their now freely accessible rear sides onto a grinding, lapping or polishing disk.

The thinning by grinding of the semiconductor wafer is continued from the rear side until the separating grooves are uncovered and ground-thin semiconductor chips of the semiconductor chip positions are present on the protective film. The protective film then ensures that the semiconductor chips are held together in their separate positions as semiconductor slice with separating grooves. The abovementioned adhesive film composed of a precurable adhesive can then be applied to the free rear side of the semiconductor chip. In this case, the adhesive film preferably comprises, in its entire thickness, an adhesive that can be procured by means of UV irradiation.

This method of UV irradiation has the advantage that the adhesion to the supporting and transporting film is reduced by the precuring in such a way that, during the lift-off of the semiconductor chips, the procured adhesive layer remains on the rear sides of the semiconductor chips.

In order to ensure the removal of the protective film, a film whose adhesion to the rear sides of the semiconductor chips is higher than the adhesion of the protective film to the top sides of the semiconductor chips is provided as the adhesive film. Otherwise there would be the risk of semiconductor chips sticking to the protective film upon the removal of the protective film and being responsible for a high level of rejects. On the other hand, it is also possible to provide a protective film having higher adhesion to the semiconductor chips and to remove the protective film by means of sputtering from the top side of the semiconductor chips. Such sputtering or ashing can be carried out with the aid of a plasma atmosphere. Furthermore, it is possible, if the adhesion of the protective film on the top side of the semiconductor 10 chips is too high, to achieve the removal of the protective film from the top side by dissolution of the protective film in a solvent. Finally, the protective film can be effected from the top side by swelling of the protective film in a solvent with subsequent facilitated pulling off since the adhesion of the protective film to the top side of the semiconductor chips is reduced by the swelling.

For the further processing of the semiconductor wafer separated into semiconductor chips, the supporting and transporting film preferably has a mounting frame. The mounting frame stabilizes the composite body composed of supporting and transporting film and adhesive film during the introduction of the separating joints. It also serves for aligning the separating joints with the separating grooves of the thinned semiconductor chips. Finally, with the mounting frame after the irradiation and precuring of the adhesive of the adhesive film, the semiconductor chips of a semiconductor wafer can be fed 30 to an automatic singulation and/or placement machine. This mounting frame has the advantage that the supporting film can inherently be made extremely thin since it is spanned and held level by a solid mounting frame.

In one preferred exemplary implementation of the method, it is provided that the lift-off of the thinned semiconductor chips with precured adhesive layer on their rear sides from the supporting and transporting film is effected by means of a stylus. Said stylus pierces the supporting and transporting film and raises the thinned semiconductor wafer to an extent such that it can be accepted by a vacuum pipette for further transport. This exemplary implementation of the method has the advantage over the method known from the document DE 101 59 974 that now a thinned semiconductor chip is available which has already been provided with an applied, non-cured adhesive layer. Consequently, in a further step of the method, the thinned semiconductor chip for further processing to form a semiconductor device with the non-cured adhesive layer on its rear side can be adhesively bonded onto a semiconductor chip position of a system carrier. Such a system carrier may be a wiring substrate of a BGA housing (Ball Grid Array Housing) or a chip island of a leadframe or a further chip.

To summarize, it can be established that with the invention, by means of an additional process step in the process chain from the thinning of a semiconductor wafer to the singulation of the ground-thin semiconductor chips, a thinned semiconductor chip with an adhering adhesive layer can be removed from a supporting and transporting film and be supplied directly for further processing. In this case, the adhesive is constituted such that it precures upon corresponding irradiation and enables a semiconductor chip with an applied adhesive layer to be available for further processing. The advantages of this method are listed in summary below.

1. The process is fully compatible with the process of thinning semiconductor wafers by grinding, which is also called “dicing before grinding” (DBG process).

2. The process can be effected over the whole area over the entire wafer produced according to the “DBG” process.

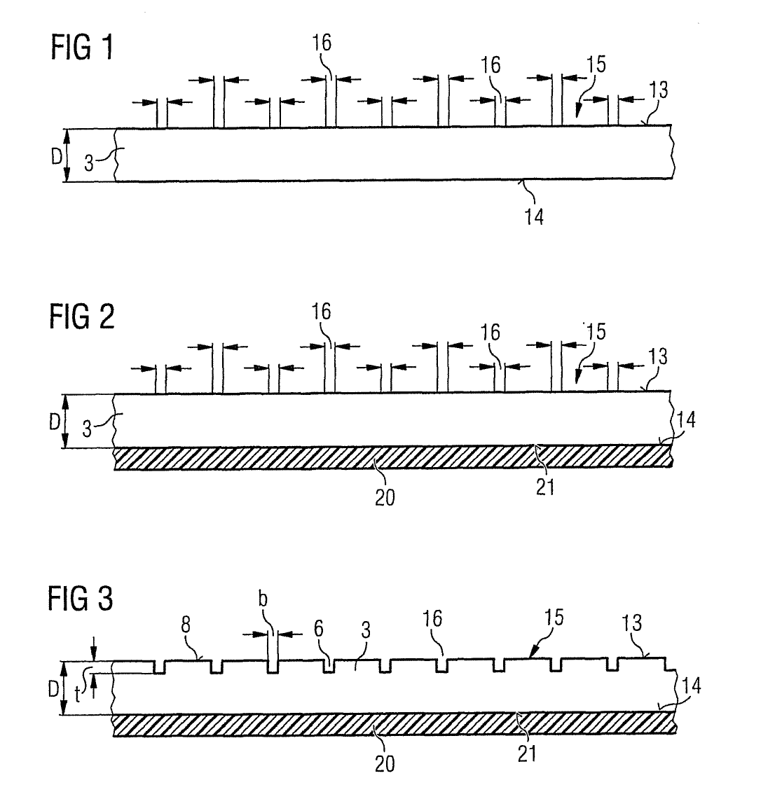

The invention will now be explained in more detail with the aid of the attached figures. The sequence of a method in which a semiconductor wafer is separated into semiconductor chips and thinned by grinding is described with the aid of FIGS. 1 to 14 below, the application of an adhesive layer to the rear side of the thinned semiconductor chips of said semiconductor wafer being realized simultaneously in the context of this method.

FIG. 1 shows a schematic cross section through a semiconductor wafer;

FIG. 2 shows a schematic cross section through the semiconductor wafer in accordance with FIG. 1 after the application of the semiconductor wafer to a wafer holder;

FIG. 3 shows a schematic cross section through the semiconductor wafer in accordance with FIG. 2 after the introduction of separating grooves;

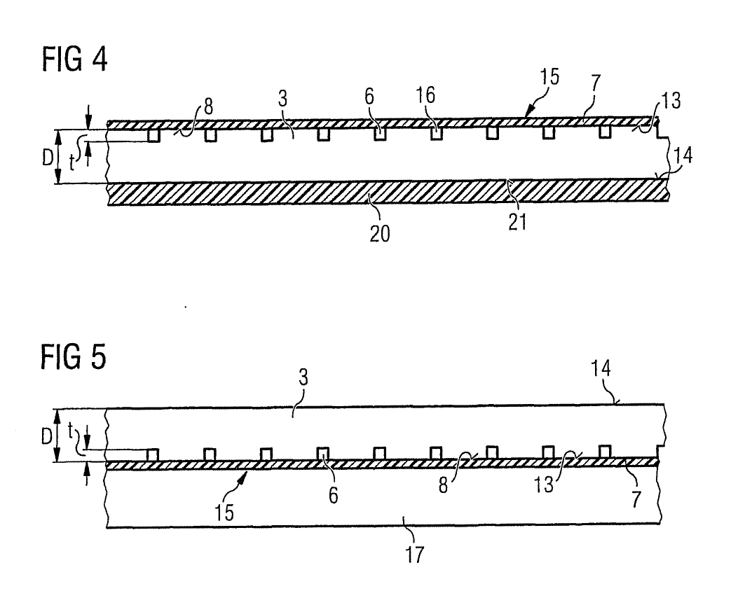

FIG. 4 shows a schematic cross section through the semiconductor wafer in accordance with FIG. 3 after the application of a protective film to the active top side of the semiconductor wafer provided with separating grooves;

FIG. 5 shows a schematic cross section through the semiconductor wafer in accordance with FIG. 4 after the application of a supporting plate to the protective film;

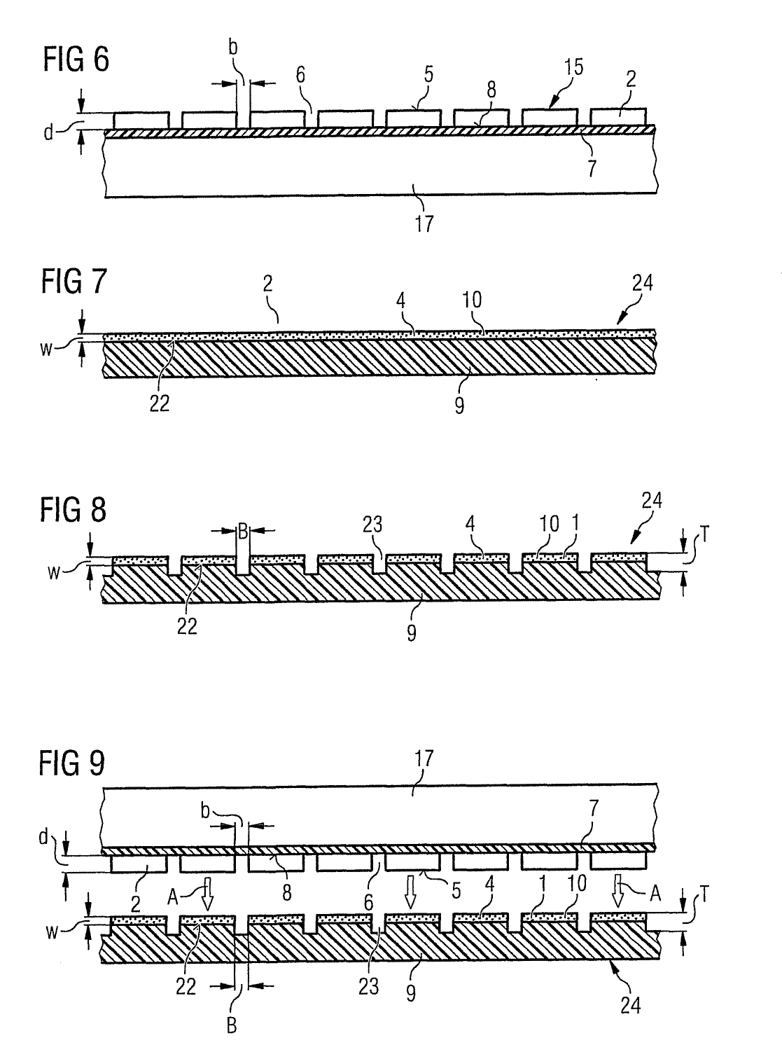

FIG. 6 shows a schematic cross section through thinned semiconductor chips on the protective film with supporting plate after thinning by grinding of the semiconductor wafer in 5 accordance with FIG. 5;

FIG. 7 shows a schematic cross section through a composite body composed of a supporting and transporting film with an applied adhesive 10 film;

FIG. 8 shows a schematic cross section through the composite body in accordance with FIG. 7 with introduced separating joints;

FIG. 9 shows a schematic cross section through the composite body in accordance with FIG. 8 and through the thinned semiconductor chips in accordance with FIG. 6;

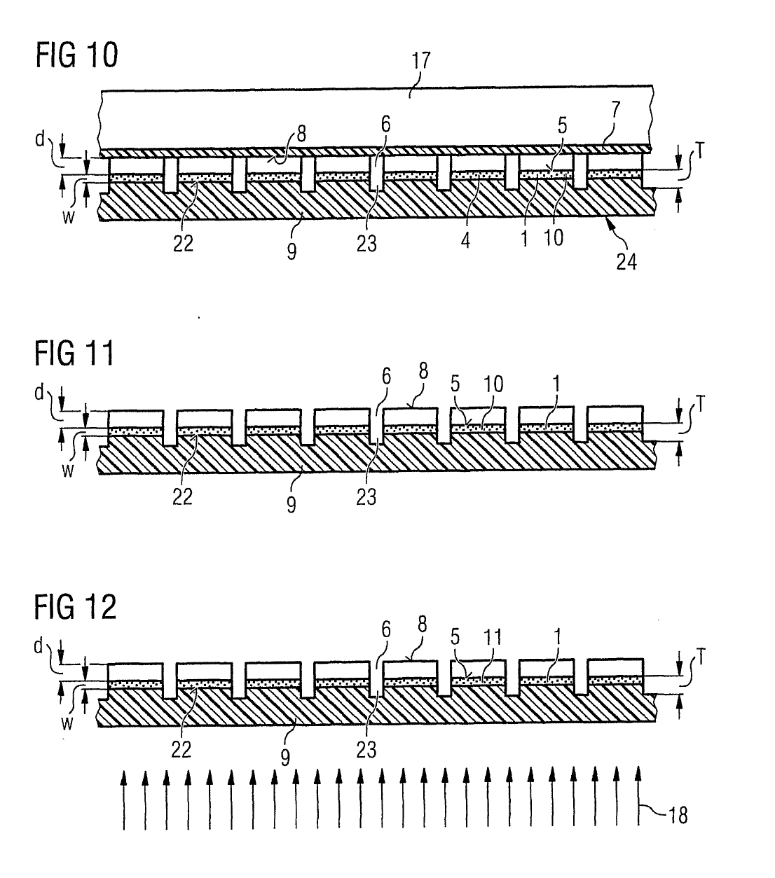

FIG. 10 shows a schematic cross section through the thinned semiconductor chips after the application of the composite body in accordance with FIG. 9;

FIG. 11 shows a schematic cross section through the thinned semiconductor chips in accordance with FIG. 10 after the removal of the supporting plate and the protective film from 30 the top sides of the semiconductor chips;

FIG. 12 shows a schematic cross section of the thinned semiconductor chips in accordance with FIG. 11 after the precuring of the adhesive film under irradiation;

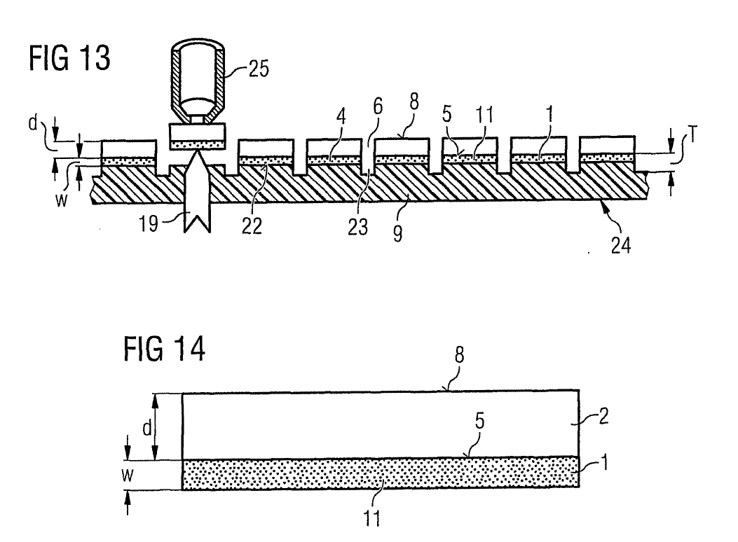

FIG. 13 shows a schematic cross section of the thinned semiconductor chip in accordance with FIG. 12 after the attachment of a stylus for lifting off one of the thinned semiconductor chips from the supporting and transporting film;

FIG. 14 shows a schematic cross section through a thinned semiconductor chip with an adhesive layer having a precured adhesive on the rear side of the thinned semiconductor chip.

FIG. 1 shows a schematic cross section through a semiconductor wafer 3 having a thickness D of 500 to 750 μm and having on its active top side 13 semiconductor chip positions 15 arranged in rows and 15 columns, while separating tracks 16 are arranged between the semiconductor chip positions 15 in order to separate the semiconductor wafer 3 into individual semiconductor chips.

FIG. 2 shows a schematic cross section through the semiconductor wafer 3 in accordance with FIG. 1 after the application of the semiconductor wafer 3 to a wafer holder 20. The semiconductor wafer 3 is applied by its rear side 14 to the wafer holder 20 of a separating apparatus, the wafer holder 20 of the separating apparatus usually being a vacuum plate that holds the semiconductor wafer 3 and its rear side 14 on the top side 21 of the wafer holder 20, while separating grooves are introduced into the top side 13 of the semiconductor wafer 3 in the regions of the separating tracks 16.

FIG. 3 shows a schematic cross section through the semiconductor wafer 3 in accordance with FIG. 2 after the introduction of separating grooves 6 into the top side 13 of the semiconductor wafer 3. The separating grooves 6 are introduced into the top side 13 of the semiconductor wafer 3 as far as a depth t, the depth t being less than the thickness D of the semiconductor wafer 3 and greater than or equal to the planned or provided thickness d of thinned semiconductor chips, such that

d≦t<D.

FIG. 4 shows a schematic cross section of the semiconductor wafer 3 in accordance with FIG. 3 after the application of a protective film 7 to the active top side 13 of the semiconductor wafer 3 provided with separating grooves 6. Said protective film 7 has a thin adhesive layer by which the protective film 7 adheres on the active top side 13 of the semiconductor wafer 3. In this case, the protective film 7 does not penetrate into the separating grooves 6.

FIG. 5 shows a schematic cross section through the semiconductor wafer 3 in accordance with FIG. 4 after the application of a supporting plate 17 to the protective film 7. Said supporting plate 17 is part of a tool of a grinding, lapping and/or polishing machine. By means of such grinding, lapping and/or polishing machines, the top sides to be ground, such as here the rear side 14 of the semiconductor wafer 3, are machined by the tool connected to the supporting plate 17 pressing said rear side 14 onto a grinding, lapping and/or polishing disk, the weight of the tool determining the contact pressure and the tool being rotationally symmetrical and causing rotation of the rear side 14 to be ground of the semiconductor wafer 3 on the grinding, lapping and/or polishing disk. In the case of lapping and polishing, the lapping and/or polishing disk is provided with a paste composed of oily liquids and abrasive micro particles in order to machine the rear side 14 of the wafer in thinning fashion.

FIG. 6 shows a schematic cross section through thinned semiconductor chips 2 on the protective film 7 with supporting plate 17 after the thinning by grinding of the semiconductor wafer 3 in accordance with FIG. 5. Since the depth of the separating grooves 6 is greater than or equal to the provided thickness d of the thinned semiconductor chips 2, the entire volume of the semiconductor wafer 3, as is shown in FIG. 5, is removed from the rear side 14 shown in FIG. 5 until the thinned semiconductor chips 2 are available separately on the protective film 7. While the active top sides 8 of the thinned semiconductor chips 2 are protected by the protective film 7, the rear side 5 of the semiconductor chips 2 is now freely accessible. An adhesive film can be applied to this rear side 5 of the thinned semiconductor chips 2 by means of the method step shown in FIG. 9.

FIG. 7 shows a schematic cross section through a composite body 24 composed of a supporting and transporting film 9 with an applied adhesive film 4. Said adhesive film 4 is constructed from a procurable adhesive 10 throughout. The adhesive film 10 has a thickness w and has the property that under irradiation its adhesion to the supporting and transporting film is reduced and the linkage between adhesive film and supporting and transporting film can be cancelled.

FIG. 8 shows a schematic cross section through the 30 composite body 24 in accordance with FIG. 7 with introduced separating joints 23. Said separating joints 23 can be introduced by sawing, scribing or cutting, as has already been described above. Introduction by vaporization by means of a laser ablation is also possible. In this case, a separating joint 23 having a depth T that is greater than or equal to the thickness w of the adhesive film 4 is introduced.

Consequently,

T≧w.

The width B and the arrangement of the separating joints 23 corresponds to the width b and arrangement of the separating grooves 6 in FIG. 6.

FIG. 9 shows a schematic cross section through the composite body 24 in accordance with FIG. 8 and through the thinned semiconductor chips 2 in accordance with FIG. 6. For this purpose, the supporting and transporting film 9 of the composite body 24 is clamped into a mounting frame and is held completely level by the mounting frame. The thinned semiconductor chips 3 are arranged with their rear sides 5 above the composite body 24 and are aligned in such a way that the separating grooves 6 and the separating joints 23 are opposite one another. The semiconductor chips 2 with their supporting plate 17 are then placed in arrow direction A onto the adhesive layers 1 made of precurable adhesive 10.

FIG. 10 shows a schematic cross section through the thinned semiconductor chips 2 after the application of the composite body 24 in accordance with FIG. 9. The semiconductor chips 2 are now seated with their rear sides 5 on the adhesive layer 1 of the composite body 24 divided into separating joints 23. The supporting plate 17 is subsequently removed from the protective layer 7 since the stability can now be undertaken by the supporting and transporting film 9, which, for its part, is held by a mounting frame.

The protective film 7 can furthermore protect the sensitive active top sides 8 of the thinned semiconductor chips 2 during transport and handling of the supporting and transporting film 9 in its mounting frame, which is not shown here. The protective film 7 applied at the start of the method in FIG. 4 during the coating of the active top side of the semiconductor wafer 3 can be used further. Consequently, below the protective film 7 and in the mounting frame with the supporting and transporting film 9, the multiplicity of thinned semiconductor chips 2 of a semiconductor wafer can advantageously be subjected to interim storage securely and without damage to the sensitive active top sides 8 of the thinned semiconductor chips 2.

FIG. 11 shows a schematic cross section through the thinned semiconductor chips 2 in accordance with FIG. 10 after the removal of the supporting plate 17 and the protective film 7 from the active top sides 8 of the thinned semiconductor chips 2. After the removal of the protective film, the top sides 8 of the semiconductor chips 2 are then completely uncovered, the separating grooves 6 extending between them and giving a clear view of the continuous supporting and transporting film 9 and also the separating joints 23. The adhesive layer 1 composed of precurable adhesive 10 is in each case arranged below the semiconductor chips 2.

FIG. 12 shows a schematic cross section through the thinned semiconductor chips 2 in accordance with FIG. 11 during the precuring of the adhesive film 4 by means of an irradiation 18. With the precuring of the adhesive material of the adhesive film 4, a reduced adhesion to the supporting and transporting film 9 is simultaneously achieved in the precured regions, while the adhesion to the rear sides 5 of the thinned semiconductor chips 2 is increased. Consequently, after the irradiation, the precured adhesive layer 1 has a lower adhesion to the surface 22 of the supporting and transporting film 9 in comparison with the adhesion between the adhesive layer 1 and the rear side 5 of the semiconductor chips 2.

FIG. 13 shows a schematic cross section through the thinned semiconductor wafer 2 in accordance with FIG. 12 after attachment of a stylus 19 for raising or lifting off one of the thinned semiconductor chips 2 from the supporting and transporting film 9. The lift-off of the thinned semiconductor chip 2 from the supporting and transporting film 9 by means of the stylus 19 is facilitated by the precured adhesive layer 1 and its minimal adhesion to the surface 22 of the supporting and transporting film 9. Furthermore, this also ensures that the thinned semiconductor chip 2 does not break or is not damaged in some other form during the lift-off process. The thinned semiconductor chip 2 is picked up after being raised by the stylus 19 by a vacuum pipette 25, such as is known from the patent specification DE 101 59 974, and is transported further for further processing in an automatic singulation and placement machine and processed further.

FIG. 14 shows a schematic cross section through a thinned semiconductor chip 2 with an adhesive layer 1, which has a precured adhesive 11 covering the rear side 5 of the thinned semiconductor chip 2. With this precured adhesive layer 1, the semiconductor chip 2 can be applied to a system carrier of a semiconductor device and be fixed there in a simple manner, such that the precurable adhesive film 4 introduced by the method step shown in FIG. 7 is found again at least in parts in the semiconductor device.

1. A method for applying an adhesive layer to ground-thin semiconductor chips of a semiconductor wafer, wherein the method has the following method steps:
application of an adhesive film, which has an adhesive that can be precured by means of irradiation, to a supporting and transporting film;
introduction of separating joints into the adhesive film, wherein the separating joints correspond in terms of arrangement and width to the arrangement and width of separating grooves of a thinned semiconductor wafer separated into thinned semiconductor chips and arranged with the active top sides of the semiconductor chips on a supporting plate;
application of the thinned and separated semiconductor wafer by its rear side to the adhesive film with the separating grooves being aligned with the separating joints;
removal of the supporting plate;
irradiation of the supporting and transporting film with precuring of the adhesive of the adhesive film for intensifying the adhesion at the rear sides of the semiconductor chips compared with the adhesion of the adhesive film to the supporting and transporting film;
lift-off of the thinned semiconductor chips with adhering adhesive film from the supporting and transporting film.

2. The method as claimed in claim 1, wherein prior to the application of the adhesive film the following method steps are carried out:
production of a semiconductor wafer having an active to side and an opposite rear side, wherein a multiplicity of semiconductor chip positions are arranged in rows and columns on the active top side, and wherein separating tracks are provided between the semiconductor chip 10 positions;
introduction of separating grooves at a predetermined width b along the separating tracks, wherein the separating grooves reach a depth t that is smaller than the thickness D of the semiconductor wafer and greater than or equal to the thickness d of the thinned semiconductor chips;
application of an adhesive protective film with a supporting plate to the top side with separating grooves;
thinning by grinding of the semiconductor wafer from its rear side until the separating grooves are uncovered and grounded-thin semiconductor chips of the semiconductor chip positions are present on the protective film.

3. The method as claimed in claim 1 or claim 2, wherein the separating joints are introduced into the composite body composed of adhesive film and supporting and transporting carrier by means of sawing technology.

4. The method as claimed in claim 1 or claim 2, wherein the separating joints are introduced into the composite body composed of adhesive film and supporting and transporting carrier by means of laser ablation technology.

5. The method as claimed in claim 1 or claim 2, wherein the separating joints are introduced into the composite body composed of adhesive film and supporting and transporting carrier by means of scribing.

6. The method as claimed in claim 1 or claim 2, Wherein the separating joints are introduced into the composite body composed of adhesive film and supporting and transporting carrier by means of cutting technology.

7. The method as claimed in one of the preceding claims, wherein a film consisting of, over its entire thickness w, an adhesive that can be precured by means of irradiation is used as the adhesive film.

8. The method as claimed in one of the preceding claims, wherein a film whose adhesion after irradiation to the rear sides of the semiconductor chips is 30 higher than the adhesion of the protective film to the top sides of the semiconductor chips is employed as the adhesive film.

9. The method as claimed in one of the preceding claims, Wherein the removal of the protective film from the top side is effected by pulling off.

10. the method as claimed in one of claims 1 to 8, wherein the removal of the protective film from the top side is effected by sputtering.

11. The method as claimed in one of claims 1 to 8, wherein the removal of the protective film rom the 10 top side is effected by dissolution in a solvent.

12. The method as claimed in one of claims 1 to 8, wherein the removal of the protective film from the top side is effected by swelling of the protective film in a solvent with subsequent pulling off.

13. The method as claimed in one of claims 1 to 8, wherein the removal of the protective film from the top side is effected by swelling of the protective film by means of heating with subsequent pulling off.

14. The method as claimed in one of the preceding claims, wherein the supporting and transporting film has a mounting frame and is mounted with the mounting frame after the irradiation and the precuring of the adhesive of the adhesive film at an automatic singulation and placement machine.

15. The method as claimed in one of the preceding claims, wherein the lift-off of the thinned semiconductor chips with precured adhesive layer from the supporting and transporting film is effected by means of a stylus that pierces the supporting and transporting film and transfers the thinned semiconductor chip to a vacuum pipette for further transport.

16. The method as claimed in one of the preceding claims, wherein the thinned semiconductor chips for further processing to form semiconductor devices with the precured adhesive layer on their rear sides are adhesively bonded on semiconductor chip positions of a wiring carrier.
